(19) United States
(12) Patent Application Publication
(10) Pub. No.: US 2026/0198274 A1
(43) Pub. Date: Jul. 9, 2026

(54) THROUGH-SUBSTRATE VIA AND METHOD OF MAKING SAME

(71) Applicant: Taiwan Semiconductor Manufacturing Company, LTD., Hsinchu (TW)

(72) Inventors: Che Wei Yang, New Taipei (TW); Zhen Yu Guan, Changhua (TW); Hung-Ling Shih, Tainan (TW); Min-Feng Kao, Chiayi (TW); Sheng-Chau Chen, Tainan (TW); Chung Yi Yu, Hsinchu (TW)

(21) Appl. No.: 19/008,961

(22) Filed: Jan. 3, 2025

(51) Int. Cl. H01L 21/768; H01L 23/48

(52) U.S. Cl. CPC H10W 20/023; H10W 20/033; H10W 20/057; H10W 20/076; H10W 20/20; H10W 20/062

(57) ABSTRACT

To form a through-substrate via (TSV), a TSV opening is formed which passes through a semiconductor substrate. A dielectric layer is coated on a sidewall and a bottom of the TSV opening. Etching is performed to remove the dielectric layer from the bottom of the TSV opening and access conductive region disposed on a distal surface of the semiconductor substrate. The etching does not remove at least a portion of the dielectric layer disposed on the sidewall of the TSV opening. The TSV opening is then filled with a conductive material to form the TSV passing through the semiconductor substrate and contacting the conductive region disposed on the distal surface of the semiconductor substrate.

### BACKGROUND

The following relates to the semiconductor arts, integrated circuit (IC) arts, silicon devices and microelectronics arts, and to methods of fabricating same.

In microelectronics, ICs, and the like, components and/or circuitry may be fabricated on both front- and backsides of a silicon wafer or other substrate. A backside through-substrate via (BTSV) is an electrically conductive via, for example, made of copper, that passes through the silicon wafer or other substrate to provide an electrical connection between the front-and backsides of the silicon wafer or other substrate.

The following discloses certain improvements.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-3 diagrammatically illustrate a through-substrate via (TSV) passing through a semiconductor substrate, where: FIG. 1 diagrammatically illustrates Cut View C1-C1 indicated in FIG. 2; FIG. 2 diagrammatically illustrates Cut View C2-C2 indicated in FIG. 1; and FIG. 3 diagrammatically illustrates Cut View C3-C3 indicated in FIG. 1, which is equivalent to a top view of the through-substrate via.

FIG. 4 diagrammatically illustrates Cut View C1-C1 presenting an isolation view of the TSV of FIGS. 1-3.

FIG. 5 diagrammatically illustrates a method of fabricating a through-substrate via.

FIGS. 6A, 6B, 6C, 6D, 6E, 6F, 6G, 6H, and 6I diagrammatically illustrate fabrication of a through-substrate via in accordance with the method of FIG. 5 by way of successive views along Cut C1-C1 indicated in FIG. 2 taken at successive steps of the fabrication process.

### DETAILED DESCRIPTION

The following disclosure provides many different embodiments, or examples, for implementing different features of the provided subject matter. Specific examples of components and arrangements are described below to simplify the present disclosure. These are merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

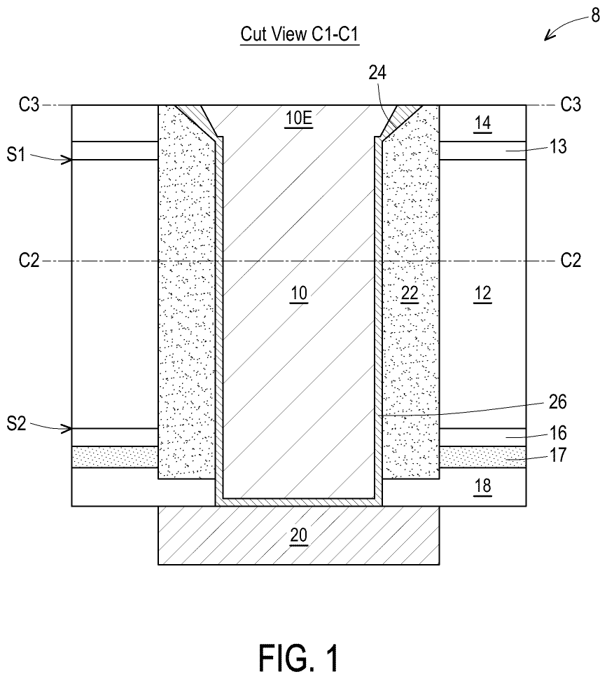

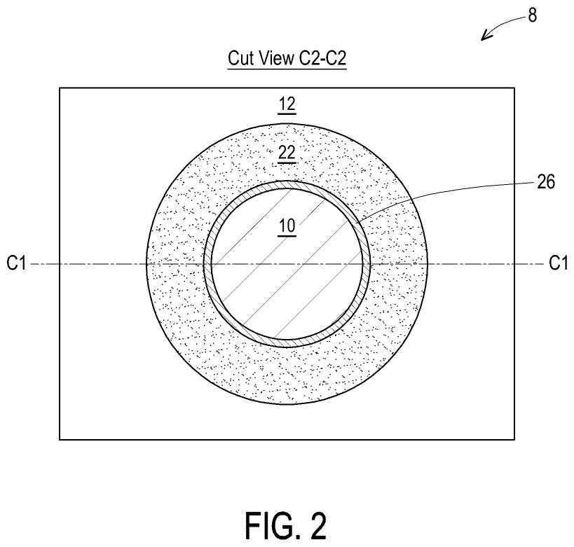

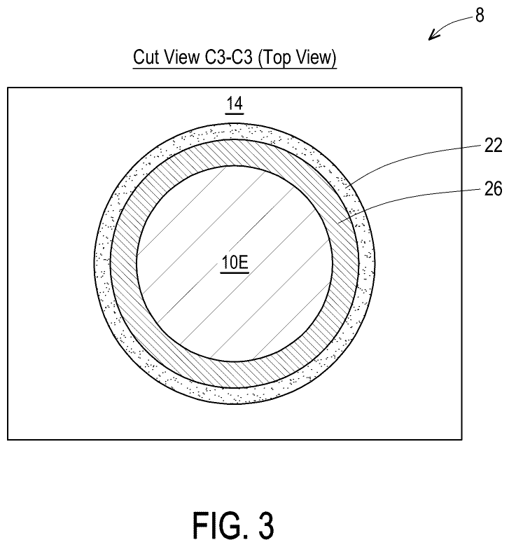

FIGS. 1-3 diagrammatically illustrate a connection structure 8, which includes a via 10 passing through a semiconductor substrate 12. FIG. 1 diagrammatically illustrates Cut View C1-C1 indicated in FIG. 2. FIG. 2 diagrammatically illustrates Cut View C2-C2 indicated in FIG. 1. FIG. 3 diagrammatically illustrates Cut View C3-C3 indicated in FIG. 1. The connection structure 8 of FIGS. 1-3 provides an electrical connection between a first principal surface S1 of the semiconductor substrate 12 and a second principal surface S2 of the semiconductor substrate, where the second principal surface S2 is opposite the first principal surface S1. Note that FIG. 3 can also be considered to be diagrammatically illustrating a top view of the connection structure 8 including the via 10, looking down at the first principal surface S2.

The semiconductor substrate 12 comprises a semiconductor material. In some nonlimiting illustrative examples, the semiconductor substrate 12 is a silicon substrate, which may be a semiconductor wafer, a rectangular silicon substrate (e.g., cut from a wafer), or so forth. In some other nonlimiting illustrative examples, the semiconductor substrate 12 may be: a germanium substrate, which may be a germanium wafer; a gallium arsenide (GaAs) substrate, which may be a GaAs wafer; a silicon on insulator (SOI) substrate, which may be an SOI wafer; or so forth. As previously mentioned, the semiconductor substrate 12 has a first principal surface S1 and a second principal surface S2, with the first and second principal surfaces S1 and S2 being on opposite sides of the semiconductor substrate 12.

In integrated circuit (IC) fabrication, the frontside of the semiconductor substrate commonly refers to the principal surface on which is fabricated the semiconductor devices of the IC, such as planar transistors, field-effect transistors (FETs), metal-oxide-semiconductor FETs (MOSFETs), FinFETs, gate-all-around FETs (GAA-FETs), diodes, inductors, resistors, various combinations thereof, and/or so forth. The opposite surface in this context is then referred to as the backside. Hence, the first principal surface S1 of the semiconductor substrate 12 is also sometimes referred to herein as a backside (or back side or back surface) S1 of the semiconductor substrate 12; and likewise, the second principal surface S2 of the semiconductor substrate 12 is sometimes referred to herein as a frontside (or front side or front surface) S2 of the semiconductor substrate 12.

The illustrative via 10 passes between the first (or backside) principal surface S1 of the semiconductor substrate 12 to the second (or frontside) principal surface S2 of the semiconductor substrate 12. As such, the via 10 is also referred to herein as a through-substrate via (TSV) 10. If the semiconductor substrate 12 is a silicon substrate, then the TSV 10 may also be considered to be a through-silicon via. The TSV 10 provides electrical connection between the second (or frontside) principal surface S2 and the first (or backside) principal surface S1. While the drawings herein show a single illustrative TSV 10, it will be appreciated that any number of TSVs 10 may be formed which pass through the substrate 12, and the TSVs 10 may be used for various purposes. As one nonlimiting illustrative purpose, in the final fabricated IC the TSVs 10 may provide electrical connection between semiconductor devices of the IC fabricated on the frontside S2 and bonding bumps, such as a ball grid array (BGA), microbumps array, or the like, disposed on the backside S1. This is merely a nonlimiting illustrative example. The TSV 10 may in some embodiments be formed by etching a via opening starting from the backside S1, so that the TSV 10 may in such a context also be referred to as a backside through-substrate via (BTSV) 10, because in such embodiments the via opening for the TSV 10 is etched from the backside S1 of the semiconductor substrate.

The first principal surface S1 of the semiconductor substrate may optionally have one or more coatings, metal regions, or other elements disposed thereon; and similarly the second principal surface S2 of the semiconductor substrate may optionally have one or more coatings, metal regions, or other elements disposed thereon. In the illustrative example of FIG. 1, the illustrative first principal surface S1 of the semiconductor substrate 12 has two coatings, namely a high-k (HK) dielectric coating 13 and a masking layer 14. The illustrative second principal surface S2 of the semiconductor substrate 12 has three coatings, namely: a resist protective oxide (RPO) layer 16, a contact etch stop layer (CESL) 17, and an interlayer dielectric (ILD) 18. In some nonlimiting illustrative examples, the HK dielectric coating 13 on the first principal surface S1 of the semiconductor substrate 12 may have a thickness of a few tens to a few hundreds of angstroms, and the masking layer 14 may have a thickness of a few thousand angstroms. These are merely some nonlimiting illustrative thickness ranges, and moreover there may be more, fewer, and/or different layers disposed on the first principal surface S1 of the semiconductor substrate 12. The RPO layer 16 may, for example, serve as a protective layer for soldering or otherwise bonding electrical contacts to the frontside S2 of the semiconductor substrate 12, for example when packaging an IC fabricated on the frontside S2 of the semiconductor substrate. The CESL 17 may serve as an etch stop during back end-of-line (BEOL) processing which forms a frontside metallization stack comprising the ILD 18 and a first (M1) patterned metallization layer (which includes a conductive region 20 shown in FIG. 1, for example). The metallization stack may include subsequently formed M2, M3, M4, . . . metallization layers with intervening ILD, not shown, with the metallization stack being formed by an iterative process including depositing an ILD layer, forming and filling via openings in the ILD layer to form vias passing through the ILD layer, forming and patterning a metal layer (e.g., the M1 layer), and repeating for each subsequent layer M2, M3, . . . . In some nonlimiting illustrative examples, the RPO layer 16 may have a thickness of a few hundred angstroms; the CESL 17 may have a thickness of a few hundred angstroms, and the ILD 18 may have a thickness of a thousand angstroms or thicker. These are merely some nonlimiting illustrative thickness ranges, and moreover there may be more, fewer, and/or different layers disposed on the second principal surface S2 of the semiconductor substrate 12.

With particular reference to FIG. 1, the illustrative conductive region 20 is disposed on the second principal surface S2 of the semiconductor substrate 12. In some embodiments, the conductive region 20 may be the first (e.g., M1) metallization layer of the metallization stack formed during BEOL processing. The TSV 10 passes through the semiconductor substrate 12, and is in contact with the conductive region 20 disposed on the second principal surface S2 of the semiconductor substrate 12.

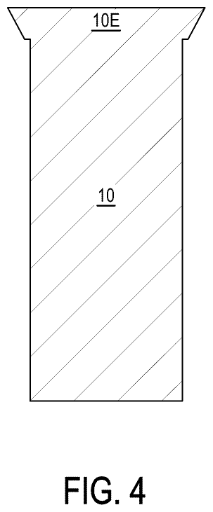

With continuing reference to FIG. 1, return reference to FIG. 3, and with brief further reference to FIG. 4 which diagrammatically illustrates Cut View C1-C1 presenting an isolation view of the TSV 10 of FIGS. 1-3, the TSV 10 includes an outwardly flared distal end 10E that is distal from the second principal surface S2. As best seen in FIG. 3, the outwardly flared distal TSV end 10E provides a larger area at the first principal surface S1 for contacting the flared distal TSV end 10E. For example, this larger area may advantageously enable less precise tolerances for placement of balls of a backside ball grid array (BGA, not shown), microbumps, or other contact element disposed at the first principal surface S1 of the semiconductor substrate 12.

With continuing reference to FIGS. 1-3, a dielectric jacket 22 comprising a dielectric material is disposed on the TSV 10. The dielectric jacket 22 includes a slanted inner surface 24 which conforms with the outwardly flared distal TSV end 10E of the TSV 10. The illustrative TSV 10 is formed by electro-chemical plating to fill a pre-formed TSV opening with copper. The electro-chemical plating process may optionally include initial deposition of a barrier layer 26 on the dielectric jacket 22. For example, in a nonlimiting illustrative example the barrier layer 26 is a barrier to migration of copper (assuming a nonlimiting illustrative example in which the TSV 10 comprises copper), and the copper barrier layer 26 may comprise titanium nitride (TiN) or tantalum nitride (TaN).

The illustrative TSV 10 has a circular cross-section, as seen in FIGS. 2 and 3. However, the TSV may have a different cross-section, such as a rectangular cross-section, an elliptical cross-section, a hexagonal cross-section, an octagonal cross-section, or so forth.

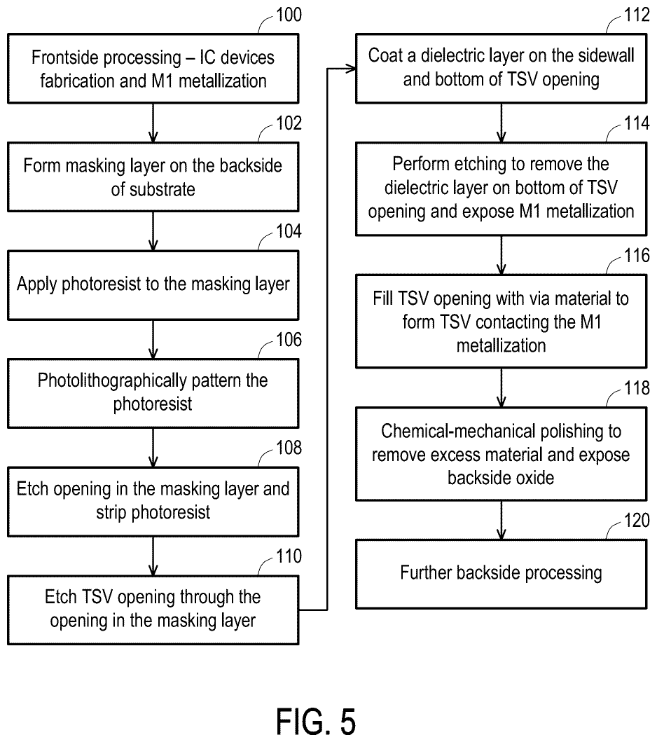

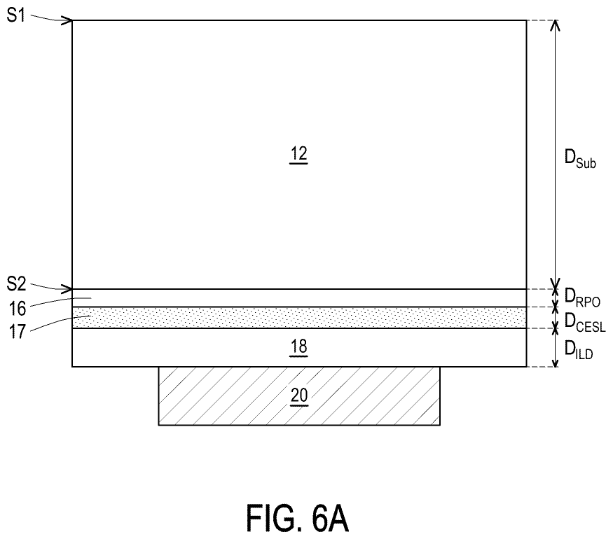

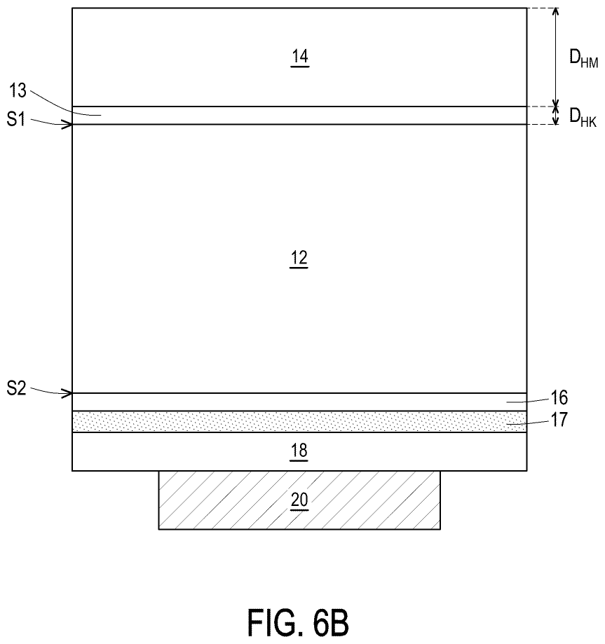

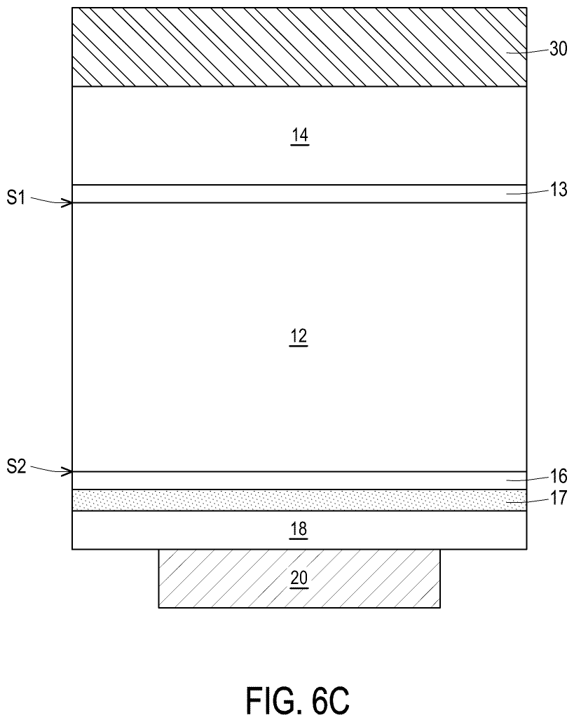

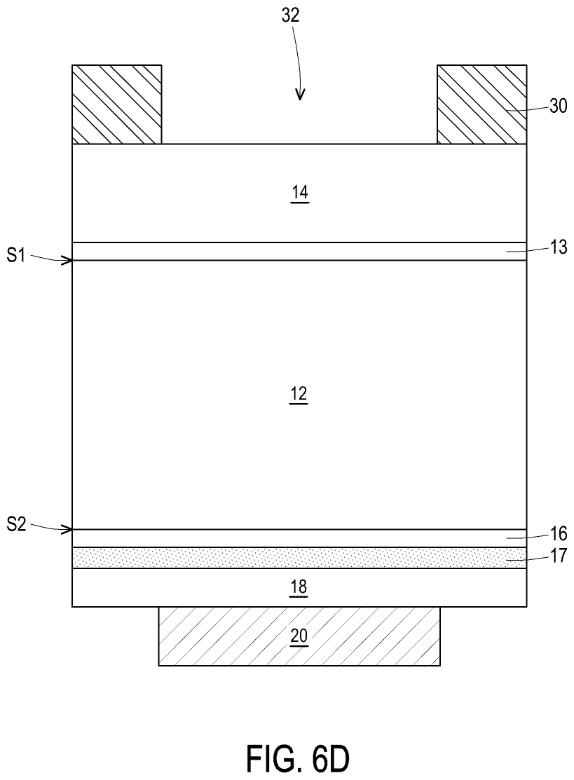

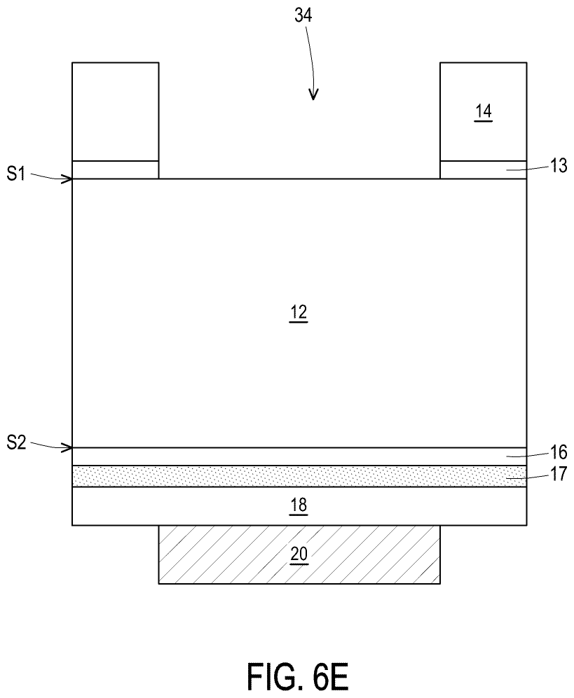

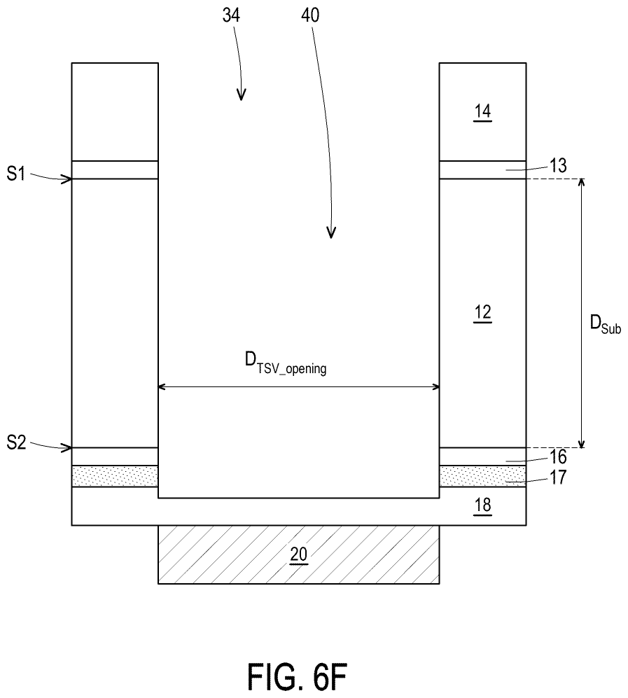

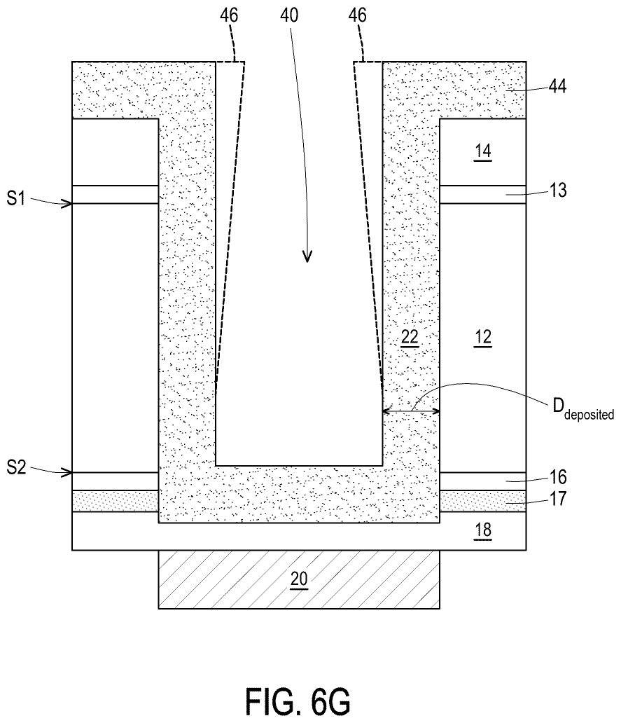

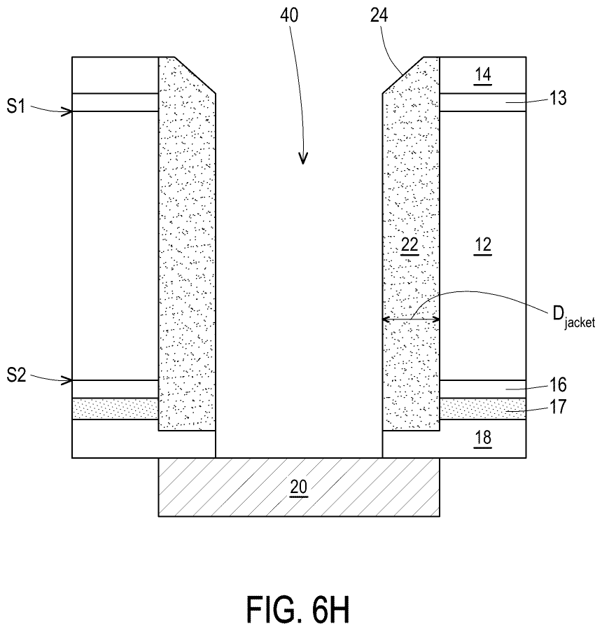

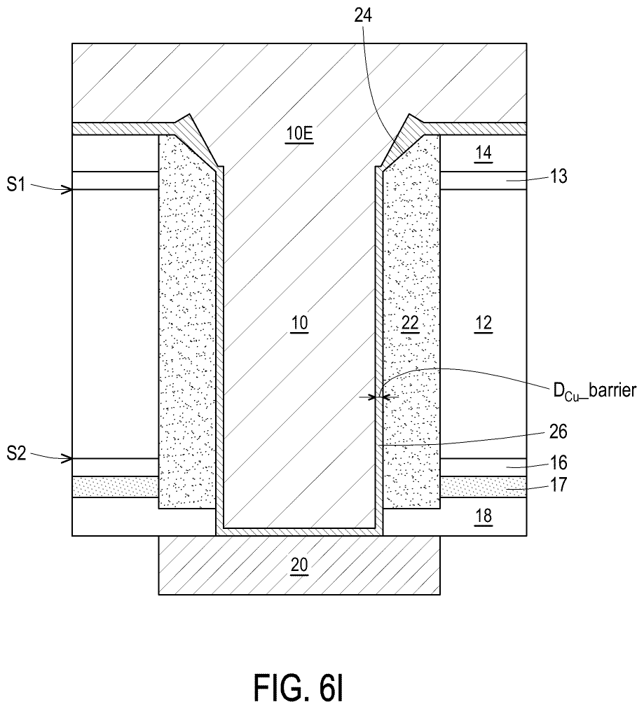

Some suitable methods for fabricating the TSV 10 are now described with reference to FIG. 5 which shows a flowchart of a fabrication workflow, and with further reference to FIGS. 6A, 6B, 6C, 6D, 6E, 6F, 6G, 6H, and 6I which diagrammatically illustrate the fabrication of the TSV 10 in accordance with the method of FIG. 5 by way of successive views along Cut C1-C1 indicated in FIG. 2, with the cut views taken at successive steps of the fabrication process.

In an operation 100, frontside processing, also known as front end-of-line (FEOL) processing, is performed to fabricate IC devices such as planar transistors, FETs, MOSFETs, FinFETs, GAA-FETs, diodes, inductors, resistors, various combinations thereof, and/or so forth on the frontside S2 of the semiconductor substrate 12. The operation 100 can employ any suitable IC device fabrication workflow, e.g., a FinFET workflow, a GAA-FET workflow, or so forth, and may include a predetermined sequence of processing steps such as deposition and/or etching steps, using photolithographic patterning or the like to delineate areas over which the deposition and/or etching is performed. The operation 100 further includes the initial BEOL processing, including in the illustrative example depositing the RPO layer 16, CESL 17, and ILD 18 on the frontside S2, and formation of the M1 metallization layer which includes the illustrative conductive region 20. This processing produces the structure shown in FIG. 6A. (Note again that the drawing herein focus on the TSV 10, and accordingly omit depiction of the IC devices and potentially other features of the IC formed in the FEOL processing.

In an operation 102 and with particular reference to FIG. 6B, the HK dielectric coating 13 and the masking layer 14 are formed on the backside S1 of the semiconductor substrate 12. Optionally, preparatory to operation 102 the semiconductor substrate may be mounted “frontside-down” with the frontside S2 bonded to adhesive tape or the like to hold the semiconductor substrate 12 in a fixed position with the backside S1 exposed for processing. The HK dielectric coating 13 may have a thickness D_{HK} of a few tens to a few hundreds of angstroms in some nonlimiting illustrative embodiments. Moreover, in some embodiments the HK dielectric coating 13 may be omitted, and/or additional coatings may be applied prior to the masking layer 14.

The masking layer 14 may also be referred to herein as a hard mask 14. The masking layer 14 may, for example, comprise silicon dioxide (SiO₂), silicon oxide (SiO), silicon nitride (SiN), silicon oxynitride (SiON), aluminum oxide (AlO), hafnium oxide (HfO), or so forth, of various stoichiometries. In some nonlimiting illustrative examples, the masking layer 14 may be a high density plasma (HDP) oxide such as silicon dioxide deposited by HDP deposition, as HDP deposition advantageously provides high deposition rate facilitating forming a relatively thick hard mask 14. During subsequent processing, the masking layer 14 is patterned, and may also be thinned by etch processing - hence, an initial thickness D_{HM} of the masking layer 14 at the processing stage shown in FIG. 6B may in some embodiments be thicker than the masking layer 14 will be in the final device (e.g., as shown in FIG. 1). In various nonlimiting illustrative examples, the initial thickness D_{HM} of the masking layer 14 may be in a range of 100-1000nm, although thicknesses outside this range are also contemplated.

In an operation 104 and with particular reference to FIG. 6C, a photoresist layer 30 is applied to the hard mask 14. For example, the photoresist layer 30 may be applied by a spin-on technique or the like.

In an operation 106 and with particular reference to FIG. 6D, the photoresist is patterned. To this end, in a photolithography exposure step, the photoresist layer 30 is exposed to light at a photolithography wavelength using a photolithography mask (i.e., photomask) to expose a region destined to correspond to the area of the TSV 10, thus creating a latent image in the photoresist 30 corresponding to the area of the TSV 10 (this is the case for a positive photoresist; in the case of a negative photoresist, the exposed area excludes the area where the resist is to be removed). The photolithography exposure step is followed by an optional bake step. Thereafter, the latent image is developed using a suitable developer chemical or chemical mixture to form an opening 32 in the photoresist 30 corresponding to the destined area of the TSV 10. It is again noted that the drawings are illustrating (fabrication of) a single TSV 10; in practice, a plurality of TSV's may be fabricated simultaneously, e.g., by employing a photomask that forms an instance of the opening 32 for each TSV to be fabricated.

In an operation 108 and with particular reference to FIG. 6E, an opening 34 is etched in the masking layer (i.e., hard mask) 14, and the photoresist is stripped. (Alternatively, the photoresist may be stripped at a later stage in the fabrication process. The etching to form the opening 34 in the hard mask 14 uses an etchant that preferentially etches the material of the hard mask 14 over the material of the photoresist. In some nonlimiting illustrative examples, dry etching may be used. In some nonlimiting illustrative examples in which the material of the hard mask 14 is silicon oxide (e.g., silicon dioxide), dry etching using carbon tetrafluoride (CF₄), trifluoromethane (CHF₃) or another suitably selective etchant may be employed. These are merely nonlimiting illustrative examples. Again, in practice a plurality of openings 34 may be simultaneously formed in the hard mask 14 by the etching, with each instance of the opening 14 corresponding to a TSV to be fabricated.

In an operation 110 and with particular reference to FIG. 6F, the opening 34 in the hard mask 14 then serves to pattern etching of a TSV opening 40 which passes through the semiconductor substrate 12 from the first principal surface (i.e., backside) S1 of the semiconductor substrate 12 to the second principal surface (i.e., frontside) S2 of the semiconductor substrate 12, as shown in FIG. 6F. Hence, the TSV opening 40 passes through the semiconductor substrate 12. The TSV opening 40 is aligned with the conductive region 20 disposed on the second principal surface S2 of the semiconductor substrate 12, as the TSV opening 40 will be subsequently filled with conductive material (e.g., copper) to form the TSV 10 contacting the conductive region 20 disposed on the second principal surface S2 of the semiconductor substrate 12. (Note, however, that at the fabrication stage shown in FIG. 6F, the TSV opening 40 lands on the ILD 18 on which the conductive region 20 is disposed.) In the illustrative example, the etching to form the TSV opening 40 is performed starting from the backside 10 of the semiconductor substrate 12, and hence the resulting TSV may also be referred to herein as a backside through-substrate via (BTSV). The etching used to form the TSV opening 40 may be an etch that preferentially etches the material of the semiconductor substrate 12 over the material of the hard mask 14. In some nonlimiting illustrative examples, the etching is a plasma-assisted dry etch process. For a nonlimiting illustrative example in which the material of the semiconductor substrate is silicon and the material of the hard mask 14 is silicon oxide (e.g., silicon dioxide), a plasma-assisted dry etch process employing a fluorine-or chlorine-based etchant is suitable, although other etchants are also contemplated. The etching may be anisotropic (e.g., as in the case of some types of dry etching) so as to provide relatively vertical sidewalls for the TSV opening 40, although some slant, curvature, or other non-verticality of the sidewalls may be present. If the ratio D_{Sub}/D_{TSV_opening} of the thickness D_{Sub} of the semiconductor substrate 12 to the diameter (or size) D_{TSV_opening} of the TSV opening 40 is small enough, an isotropic etch could also be suitable. This could be the case if, for example, the substrate has been thinned in a previous step (not shown).

In some embodiments, a layer disposed on the second surface S2 and laterally aligned with the TSV opening 40 may serve as an etch stop for the etching that forms the TSV opening 40. For example, in FIG. 6F the ILD 18 may optionally serve as an etch stop for the etching which forms the TSV opening 40. In another contemplated embodiment, the conductive region 20 could serve as the etch stop. These are merely some nonlimiting illustrative examples.

The illustrative TSV opening 40 has a diameter D_{TSV_opening} (or other suitable characteristic cross-sectional dimension, if the TSV opening is noncircular) as labeled in FIG. 6F. In some nonlimiting illustrative examples, the diameter D_{TSV_opening} may be in a range of 0.1 micron to 10 microns, although values outside this range are also contemplated. Again, in practice a plurality of TSV openings 40 may be simultaneously formed by the etching, with each instance of the TSV opening 40 corresponding to a TSV to be fabricated.

In an operation 112 and with particular reference to FIG. 6G, a dielectric layer 44 is coated on the sidewall and bottom of TSV opening 40. The portion of dielectric layer 44 that is deposited on the sidewall of the TSV opening 40 corresponds to the dielectric jacket 22 of the final fabricated TSV (e.g., as shown in FIGS. 1-3). However, it is noted that the portion of dielectric layer 44 that is deposited on the sidewall of the TSV opening 40 may be thinned during a subsequent etching process, so that the dielectric jacket 22 on the sidewall of the final fabricated TSV may be thinner than the as-deposited dielectric layer 44. The illustrative dielectric layer 44 is silicon dioxide (SiO₂), and a thickness of the as-deposited dielectric layer 44 is indicated in FIG. 6G as thickness D_{deposited}. However, the dielectric layer 44 may in general comprise another dielectric material such as silicon oxide (SiO), silicon nitride (SiN), silicon oxynitride (SiON), aluminum oxide (AlO), hafnium oxide (HfO), or so forth.

Referring briefly back to FIGS. 1-4, the dielectric jacket 22 of the connection structure 8 provides electrical isolation of the TSV 10 from the surrounding semiconductor substrate 12, which may be electrically conductive. The illustrative dielectric layer 44 is a conformal dielectric layer, in that it generally conforms with the shape of the TSV opening 40, and in particular coats the sidewall and bottom of the TSV opening 40, as well as coating the masking layer 14 which is disposed on the backside surface S1 of the semiconductor substrate 12. In the illustrative example, the portion of the dielectric layer 44 deposited on the sidewall of the TSV opening 40 has no overhang.

FIG. 6G also diagrammatically indicates the shape of such an overhang by dashed lines 46. In some approaches for fabricating a connection structure comprising a TSV, a dielectric material is deposited in such a way as to have such an overhang 46. The purpose of the overhang 46 in such approaches is that the overhang protects the dielectric jacket coated on the sidewall of the TSV opening 40 during a subsequent etching step (to be described hereinafter with reference to FIG. 6H). As an example of such an approach for fabricating a connection structure comprising a TSV, a thin conformal oxide layer may be deposited, followed by deposition of silicon nitride (SiN) by plasma-enhanced chemical vapor deposition (PECVD). The deposition of silicon nitride by PECVD produces an overhang 46, which then protects the thin conformal oxide layer. However, while such an overhang 46 can protect the thin oxide layer coating the sidewall of the TSV opening, it produces a constriction of the open upper end of the TSV opening. Put another way, the diameter (or other principal lateral dimension) of the TSV opening is constricted at the backside surface S1 of the semiconductor substrate 12. Such a constriction can cause subsequent filling of the TSV opening with copper (or another conductive material, to be described hereinafter with reference to FIG. 6I) to be incomplete, potentially leading to a void in the TSV that can reduce its electrical conductance (i.e., increase resistance of the TSV) and present a failure point.

By contrast, in the method of fabricating a through-substrate via described herein with reference to FIGS. 6A-6I, does not rely on an overhang 46 to protect the dielectric jacket 22 during fabrication. Rather, the dielectric layer 44 is deposited at an as-deposited thickness D_{deposited} indicated in FIG. 6G, that is larger than a final thickness D_{jacket} (labeled in FIG. 6H to be described) of the dielectric jacket 22. The additional thickness serves as sacrificial material during the subsequent etching.

In some nonlimiting illustrative embodiments, the dielectric layer 44 is deposited by atomic layer deposition (ALD), and in some such embodiments more particularly by plasma-enhance atomic layer deposition (PEALD) which provides fast atomic layer deposition to facilitate depositing the dielectric layer 44 with a relatively large as-deposited thickness D_{deposited}. Use of ALD or PEALD also advantageously provides conformal deposition so as to avoid or minimize any overhang. In this regard, it is noted that while FIG. 6G illustrates the dielectric layer 44 with no overhang, variant embodiments with some minimal overhang are contemplated. Similarly, while FIG. 6G illustrates the dielectric layer 44 with an abrupt right-angle (90 degree) corner between the portion of the dielectric layer 44 coating the sidewall of the TSV opening 40 and the portion of the dielectric layer 44 coating the backside surface S1, variant embodiments with a slope, curve, or inward slant (i.e., underhang) are contemplated. These variants can be produced by different deposition conditions for the ALD, PEALD, or other type of deposition used to form the dielectric layer 44.

In an operation 114 and with particular reference to FIG. 6H, etching is performed to remove the dielectric layer 44 from the bottom of the TSV opening 40 and access the conductive region 20 disposed on the second principal surface S2 of the semiconductor substrate 12. The etching does not remove at least a portion of the dielectric layer 44 disposed on the sidewall of the TSV opening 40 (as shown in FIG. 6G). In some embodiments, the etching comprises plasma-assisted dry etching, which provides anisotropic etching that more quickly etches the portion of the dielectric layer 44 disposed on the bottom of the TSV opening 40 than it does the portion of the dielectric layer 44 disposed on the sidewall of the TSV opening 40. However, in some embodiments the plasma-assisted dry etching (or other utilized type of etching) does etch the portion of the dielectric layer 44 disposed on the sidewall of the TSV opening 40, so that after the etching the remaining dielectric jacket 22 has a reduced thickness D_{jacket} compared with the as-deposited thickness D_{deposited} indicated in FIG. 6G. In such embodiments, the as-deposited thickness D_{deposited} is designed to be thick enough so that after the etching the remaining thickness D_{jacket} of the dielectric jacket 22 is thick enough to provide the desired electrical isolation of the TSV 10 from the surrounding material of the semiconductor substrate 12.

In the embodiment of FIG. 6H, the etching also removes some of the uppermost region of the portion of the dielectric layer 44 disposed on the sidewall of the TSV opening 40, thereby producing the slanted inner surface 24 of the dielectric jacket 22. In the final connection structure 8 (see FIGS. 1-3), the slanted inner surface 24 of the dielectric jacket 22 will conform with the outwardly flared distal TSV end 10E of the TSV 10, advantageously providing a larger exposed surface area for the TSV 10 which may enable less precise tolerances for placement of balls of a BGA, microbump, or other contact element disposed at the backside surface S1 of the semiconductor substrate 12. The slanted inner surface 24 of the dielectric jacket 22 is produced because the ions bombarding the backside surface S1 during the plasma-assisted dry etching have kinetic energies primarily directed downward (in the orientation shown in FIG. 6H), i.e., primarily directed parallel with the central axis of the TSV opening 40, so that they bombard the uppermost region of the portion of the dielectric layer 44 disposed on the sidewall of the TSV opening 40 more than further down along the sidewall, thereby producing the slanted inner surface 24.

As further seen in FIG. 6H, the etching also removes the portion of the dielectric layer 44 disposed on the masking layer 14 disposed on the backside surface S1 of the semiconductor substrate 12. In some embodiments, in addition the etching may remove an upper portion of the masking layer 14 itself. To accommodate this, the masking layer 14 may have an initial thickness which is sufficient so that a desired final thickness for the masking layer 14 remains after the etching.

The workflow described above with particular reference to steps 112 and 114 of FIG. 5 and with particular reference to FIGS. 6G and 6H has advantages, including enabling the formation of the dielectric jacket 22 comprising a single layer of a single oxide material or other single dielectric material (as opposed to two depositions of different materials, e.g., an oxide followed by SiN, with the SiN deposition providing protective overhang 46 indicated in FIG. 6G), avoiding formation of a constriction due to the overhang 46 which limits the exposed surface area of the resulting TSV at the backside surface S1, and avoiding the potential for introducing a void in the TSV 10 (due to the overhang 46 in approaches using this overhang) that can reduce its electrical conductance (i.e., increase resistance of the TSV) and present a failure point.

In an operation 116 and with particular reference to FIG. 6I, after the etching just described with reference to FIG. 6H, the TSV opening 40 is filled with a conductive material to form the TSV 10 passing through the semiconductor substrate 12 from the first principal surface (e.g., backside) S1 of the semiconductor substrate 12 to the second principal surface (e.g., frontside) S2 of the semiconductor substrate 12 and contacting the conductive region 20 disposed on the second principal surface S2 of the semiconductor substrate 12. In some nonlimiting illustrative examples, the filling of the TSV opening 40 with the conductive material comprises performing electro-chemical plating (also sometimes more succinctly referred to as electroplating) to fill the TSV opening 40 with copper, such that the TSV 10 is made of copper. Alternatively, electro-chemical plating of another metal is contemplated.

Optionally, the electro-chemical plating process may include initial deposition of the optional barrier layer 26 on the dielectric jacket 22 (and, in the illustrative example, also on the electrically conductive material 20). For example, in a nonlimiting illustrative example in which the TSV 10 is copper, the copper barrier layer 26 may comprise TiN or TaN. The optional barrier layer 26 presents a barrier to migration of copper (or other material making up the TSV 10) into the surrounding semiconductor material of the semiconductor substrate 12. The optional barrier layer 26, if included, is thick enough to limit such copper outmigration, while being thin enough to not significantly impact electrical conduction through the interface between the TSV 10 and the conductive material 20 on the frontside S2 of the semiconductor substrate 12. In some nonlimiting examples, the barrier layer 26 may have a thickness in a range of 10 nm to 100 nm, although thicknesses outside this range are also contemplated.

To perform the electro-chemical plating of the copper (or other conductive material) to fill the TSV opening 40 and thereby form the TSV 10, a seed layer (e.g., of copper) may first be deposited on the barrier layer 26 (or directly onto the dielectric jacket 22 and conductive material 20, if the optional barrier layer 26 is omitted). The seed layer is typically thin, and may be formed by chemical vapor deposition (CVD), physical vapor deposition (PVD), vacuum evaporation, or any other suitable deposition technique.

As seen in FIG. 6I, both the optional barrier layer 26 and the electroplated copper also deposit on the masking layer 14. Hence, as indicated in FIG. 5, a final step 118 of chemical-mechanical polishing (CMP) is suitably performed to remove excess copper and copper barrier material from the masking layer 14, and expose (and planarize) the backside oxide masking layer 14. This results in the final connection structure 8 as shown in FIGS. 1-3. In some embodiments, the CMP 118 may also remove an upper portion of the masking layer 14 itself. (Such removal would be in addition to any removal of an upper portion of the masking layer 14 by the etching of the dielectric layer 44, as previously described with reference to FIG. 6H). Again, to accommodate this, the masking layer 14 may have an initial thickness which is sufficient so that a desired final thickness for the masking layer 14 remains after the etching and CMP.

As further indicated in FIG. 5, the CMP 118 may be followed by further backside processing 120. As some nonlimiting illustrative examples, the further backside processing 120 in various embodiments may include one or more of: placement of balls of a BGA, microbumps, or other contact elements on the TSVs 10 disposed at the backside surface S1 of the semiconductor substrate 12; forming a metallization stack, redistribution layer (RDL), or other wiring structure on the backside surface S1 of the semiconductor substrate 12 that contacts the TSVs 10 disposed at the backside surface S1 of the semiconductor substrate 12; and/or so forth. The further processing 120 may advantageously be facilitated by the surface of the (remaining) oxide masking layer 14 being exposed by the CMP 118, thereby providing an insulative oxide surface to limit contact of the BGAs, microbumps, et cetera, or to provide an insulative oxide surface on which the metallization stack, RDL, or other wiring structure can be formed.

In the following, some further embodiments are described.

In a nonlimiting illustrative embodiment, a via fabrication method comprises: forming a through-substrate via (TSV) opening passing through a semiconductor substrate from a first principal surface of the semiconductor substrate to a second principal surface of the semiconductor substrate, the TSV opening being aligned with a conductive region disposed on the second principal surface of the semiconductor substrate; coating a dielectric layer on a sidewall and a bottom of the TSV opening; performing etching to remove the dielectric layer from the bottom of the TSV opening and access the conductive region disposed on the second principal surface of the semiconductor substrate, the etching not removing at least a portion of the dielectric layer disposed on the sidewall of the TSV opening; and, after the etching, filling the TSV opening with a conductive material to form a TSV passing through the semiconductor substrate from the first principal surface of the semiconductor substrate to the second principal surface of the semiconductor substrate and contacting the conductive region disposed on the second principal surface of the semiconductor substrate.

In a nonlimiting illustrative embodiment, a via fabrication method comprises: disposing a masking layer on a backside of a semiconductor substrate; performing photolithographic processing to form an opening in the masking layer; performing first dry etching to form a through-substrate via (TSV) opening aligned with the opening in the masking layer, the TSV opening passing through the semiconductor substrate from the backside of the semiconductor substrate to a frontside of the semiconductor substrate, the TSV opening being aligned with a conductive region disposed on the frontside of the semiconductor substrate; disposing a dielectric layer on a sidewall and a bottom of the TSV opening; performing second dry etching to remove the dielectric layer from the bottom of the TSV opening and access the conductive region disposed on the frontside of the semiconductor substrate, the second dry etching not removing at least a portion of the dielectric layer disposed on the sidewall of the TSV opening; after the second dry etching, performing electro-chemical plating to form a conductive TSV which fills the TSV opening and contacts the conductive region disposed on the frontside of the semiconductor substrate; and performing chemical mechanical polishing to remove excess conductive material disposed on the backside of the semiconductor substrate by the electro-chemical plating.

In a nonlimiting illustrative embodiment, a connection structure is disclosed for connecting a first principal surface of a semiconductor substrate and a second principal surface of the semiconductor substrate opposite the first principal surface. The connection structure comprises a conductive region disposed on the second principal surface of the semiconductor substrate, and a through-substrate via (TSV) passing through the semiconductor substrate and in contact with the conductive region disposed on the second principal surface of the semiconductor substrate. The TSV includes an outwardly flared distal TSV end that is distal from the second principal surface.

In a nonlimiting illustrative embodiment, to form a through-substrate via (TSV), a TSV opening is formed which passes through a semiconductor substrate. A dielectric layer is coated on a sidewall and a bottom of the TSV opening. Etching is performed to remove the dielectric layer from the bottom of the TSV opening and access conductive region disposed on a distal surface of the semiconductor substrate. The etching does not remove at least a portion of the dielectric layer disposed on the sidewall of the TSV opening. The TSV opening is then filled with a conductive material to form the TSV passing through the semiconductor substrate and contacting the conductive region disposed on the distal surface of the semiconductor substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A via fabrication method comprising:
forming a through-substrate via (TSV) opening passing through a semiconductor substrate from a first principal surface of the semiconductor substrate to a second principal surface of the semiconductor substrate, the TSV opening being aligned with a conductive region disposed on the second principal surface of the semiconductor substrate;
coating a dielectric layer on a sidewall and a bottom of the TSV opening;
performing etching to remove the dielectric layer from the bottom of the TSV opening and access the conductive region disposed on the second principal surface of the semiconductor substrate, the etching not removing at least a portion of the dielectric layer disposed on the sidewall of the TSV opening; and
after the etching, filling the TSV opening with a conductive material to form a TSV passing through the semiconductor substrate from the first principal surface of the semiconductor substrate to the second principal surface of the semiconductor substrate and contacting the conductive region disposed on the second principal surface of the semiconductor substrate.

2. The via fabrication method of claim 1, wherein the coating comprises depositing the dielectric layer by atomic layer deposition.

3. The via fabrication method of claim 1, wherein the dielectric layer coating the sidewall of the TSV opening does not include an overhang.

4. The via fabrication method of claim 1, wherein filling the TSV opening with the conductive material deposits excess conductive material on the first principal surface of the semiconductor substrate, and the method further comprises:
after filling the TSV opening with the conductive material, performing chemical mechanical polishing to remove the excess conductive material on the first principal surface of the semiconductor substrate.

5. The via fabrication method of claim 4, wherein the forming of the TSV opening includes:
disposing a masking layer on the first principal surface of the semiconductor substrate;
performing photolithographic processing to form an opening in the masking layer; and
etching the TSV opening through the opening in the masking layer;
wherein the excess conductive material on the first principal surface of the semiconductor substrate is disposed on the masking layer; and
wherein the chemical mechanical polishing removes the excess conductive material on the first principal surface of the semiconductor substrate to expose a surface of the masking oxide layer.

6. The via fabrication method of claim 1, wherein:
the coating of the dielectric layer also coats dielectric material on the first principal surface of the semiconductor substrate, and
the etching removes the dielectric material coated on the first principal surface of the semiconductor substrate.

7. The via fabrication method of claim 1, wherein the etching also removes an upper portion of the dielectric layer coated on the sidewall of the TSV opening to produce a surface of an upper portion of the dielectric layer coated on the sidewall of the TSV opening after the etching that is slanted inward toward the TSV opening.

8. The via fabrication method of claim 1, wherein the semiconductor substrate comprises silicon and wherein:
the forming of the TSV opening comprises performing plasma-assisted dry etching;
the dielectric layer comprises an oxide layer and the coating comprises coating the oxide layer on the sidewall and the bottom of the TSV opening by plasma-enhanced atomic layer deposition;
the etching comprises plasma-assisted dry etching; and
the filling the TSV opening with the conductive material comprises performing electro-chemical plating to fill the TSV opening with copper.

9. A via fabrication method comprising:
disposing a masking layer on a backside of a semiconductor substrate;
performing photolithographic processing to form an opening in the masking layer;
performing first dry etching to form a through-substrate via (TSV) opening aligned with the opening in the masking layer, the TSV opening passing through the semiconductor substrate from the backside of the semiconductor substrate to a frontside of the semiconductor substrate, the TSV opening being aligned with a conductive region disposed on the frontside of the semiconductor substrate;
disposing a dielectric layer on a sidewall and a bottom of the TSV opening;
performing second dry etching to remove the dielectric layer from the bottom of the TSV opening and access the conductive region disposed on the frontside of the semiconductor substrate, the second dry etching not removing at least a portion of the dielectric layer disposed on the sidewall of the TSV opening;
after the second dry etching, performing electro-chemical plating to form a conductive TSV which fills the TSV opening and contacts the conductive region disposed on the frontside of the semiconductor substrate; and
performing chemical mechanical polishing to remove excess conductive material disposed on the backside of the semiconductor substrate by the electro-chemical plating.

10. The via fabrication method of claim 9, wherein the dielectric layer is deposited by plasma-enhanced atomic layer deposition.

11. The via fabrication method of claim 10, wherein the dielectric layer disposed on the sidewall of the TSV opening does not include an overhang.

12. The via fabrication method of claim 10, wherein the dielectric layer is a conformal oxide layer.

13. The via fabrication method of claim 9, wherein the dielectric layer is also disposed on the masking layer outside of the TSV opening, and the second dry etching is a plasma assisted dry etching and removes the dielectric layer from the masking layer.

14. The via fabrication method of claim 9, wherein the masking layer is a masking oxide layer, and the chemical mechanical polishing exposes the masking oxide layer.

15. A connection structure for connecting a first principal surface of a semiconductor substrate and a second principal surface of the semiconductor substrate opposite the first principal surface, the connection structure comprising:
a conductive region disposed on the second principal surface of the semiconductor substrate; and
a through-substrate via (TSV) passing through the semiconductor substrate and in contact with the conductive region disposed on the second principal surface of the semiconductor substrate, the TSV including an outwardly flared distal TSV end that is distal from the second principal surface.

16. The connection structure of claim 15, further comprising:
a dielectric jacket comprising a dielectric material disposed on the TSV, the dielectric jacket including a slanted inner surface conforming with the outwardly flared distal TSV end.

17. The connection structure of claim 16, wherein the dielectric jacket has a cylindrical outer surface.

18. The connection structure of claim 16, wherein the dielectric jacket comprises a single layer of a single dielectric material.

19. The connection structure of claim 18, wherein the single dielectric material is a single oxide material.

20. The connection structure of claim 16, wherein the TSV comprises copper.
